(19) United States
(12) Patent Application Publication
(10) Pub. No.: US 2012/0315739 A1
(43) Pub. Date: Dec. 13, 2012

(54) MANUFACTURING METHOD FOR SEMICONDUCTOR WAFER

(75) Inventors: Tomohiro Hashii, Tokyo (JP); Yuichi Kakizono, Tokyo (JP); Yoshiaki Kurosawa, Tokyo (JP)

(73) Assignee: SUMCO CORPORATION, Tokyo, (JP)

(21) Appl. No.: 13/581,011

(22) PCT Filed: Feb. 16, 2011
(86) PCT No.: PCT/JP2011/053193

§ 371 Date: Aug. 24, 2012

(30) Foreign Application Priority Data
Feb. 26, 2010 (JP) 2010-043150

(51) Int. Cl. H01L 21/78

(52) U.S. Cl. 438/460; 257/E21.599

(57) ABSTRACT

All treatments performed in machining processes other than a polishing process are performed while pure water free from free abrasive grains is supplied. Thus, an amount of abrasive grains included in a used processing liquid discharged in each process is reduced and semiconductor scraps are collected from the used slurry for recycling.

### TECHNICAL FIELD

The present invention relates to a method of manufacturing a semiconductor wafer, specifically, a method of manufacturing a semiconductor wafer by processing a semiconductor monocrystalline ingot as a raw material to produce a semiconductor wafer.

### BACKGROUND ART

A conventional method of manufacturing a semiconductor wafer is disclosed in Patent Literature 1, for example. The method of manufacturing includes slicing a monocrystalline ingot into a plurality of semiconductor wafers by a wire saw, lapping to flatten a front surface of each of the semiconductor wafers, chamfering an external peripheral portion of each of the semiconductor wafers, etching to remove processing strain of each of the semiconductor wafers, and minor-polishing the front surface of each of the semiconductor wafers. The lapping, etching, and polishing processes are each performed in a single wafer manner.

Patent Literature 1: Japanese Patent Laid-Open Publication No. H11-251270

### SUMMARY OF INVENTION

### Technical Problem

The technology of Patent Literature 1 is effective as a processing technology to deal with an increasing diameter of semiconductor wafers. In the technology, however, the slicing and lapping processes are performed while a slurry containing an oil dispersant and free abrasive grains is supplied to a semiconductor ingot and a semiconductor wafer, respectively. Semiconductor scraps generated in these processes could be resources and be recycled to be a portion of raw material for a semiconductor ingot, for example. However, the semiconductor scraps, which are included in the used slurry mixed with the oil dispersant and the free abrasive grains, require a substantial processing cost for recycling. Thus, the semiconductor scraps, which are recognized as invaluable resources, are currently disposed of.

As a result of diligent research, the inventors of the present invention have found that performing all treatments performed in machining processes, other than a polishing process, while supplying pure water free from free abrasive grains reduces an amount of abrasive grains included in used processing liquid discharged in each process and allows recycling of semiconductor scraps collected from the used slurry.

Furthermore, the inventors have found that, with use in a slicing process of a fixed abrasive grain wire having an external peripheral surface to which abrasive grains are fixed and with use of a simultaneous double-side grinder of a fixed abrasive grain type able to perform a series of processes from rough grinding to finish grinding, the number of processes to manufacture semiconductor wafers is reduced and also semiconductor scraps generated in these processes are reduced, thus leading to a reduction in kerf loss.

Specifically, an object of the present invention is to provide a method of manufacturing a semiconductor wafer that reduces an amount of semiconductor scraps generated in slicing, grinding, and chamfering processes and allows recycling of the semiconductor scraps generated in the three processes with ease and at low cost.

### Solution to Problem

A first aspect of the present invention provides a method of manufacturing a semiconductor wafer, including slicing a semiconductor monocrystalline ingot into a plurality of semiconductor wafers by using a fixed abrasive grain wire having an external peripheral surface to which abrasive grains are fixed; grinding front and rear surfaces of each of the semiconductor wafers by using fixed abrasive grain layers formed on platen surfaces; chamfering an external peripheral portion of each of the ground semiconductor wafers by using a chamfering grindstone; and polishing the front and rear surfaces of each of the ground semiconductor wafers. The slicing, the grinding, and the chamfering are performed while pure water free from free abrasive grains is supplied to one of the monocrystalline ingot and the semiconductor wafers.

According to the first aspect of the present invention, the monocrystalline ingot is sliced into a plurality of semiconductor wafers by the fixed abrasive grain wire in the slicing. In the flat surface grinding, the semiconductor wafers are processed in simultaneous double-side grinding of a fixed abrasive grain type that allows processes from rough grinding to finish grinding to be completed in one process. Thus, the number of processes to manufacture semiconductor wafers can be reduced and the kerf loss in the slicing and simultaneous double-side grinding can also be reduced.

In addition, the slicing with the fixed abrasive grain wire and the simultaneous double-side grinding of the fixed abrasive grain type reduce an amount of abrasive grains included in a used processing liquid discharged in the slicing, the simultaneous double-side grinding, and the chamfering, including the chamfering that uses the chamfering grindstone, compared to a conventional case where a slurry including free abrasive grains is used. Furthermore, pure water is used as the processing liquid to be supplied to processed objects, which are processed surfaces of the monocrystalline ingot and the semiconductor wafers. This facilitates a recycling process and reduces processing cost, compared to a conventional case where semiconductor scraps are collected for recycling from a used slurry that includes an oil dispersant and free abrasive grains.

An example of the monocrystalline ingot may be a monocrystalline silicon ingot.

An example of the semiconductor wafer may be a monocrystalline silicon wafer.

The diameter of the semiconductor wafer may be, for example, 300 mm or 450 mm.

In the slicing with the fixed abrasive grain wire, a row of wires each having a predetermined tension is reciprocated. The monocrystalline ingot is pressed against the row of wires and thus is cut (sliced) into a plurality of semiconductor wafers due to a grinding action of fixed abrasive grains.

The fixed abrasive grain wire has an external peripheral surface to which the abrasive grains are fixed. For instance, a metal plated layer containing numerous abrasive grains is coated on the surface of the wire and portions of the abrasive grains project through the surface of the metal plated layer.

Examples of the wire as a main body of the fixed abrasive grain wire may include a steel wire, such as a piano wire, a tungsten wire, and a molybdenum wire.

The diameter of the wire is 50 to 500 μm. With a diameter of less than 50 μm, a wire is likely to break. A diameter of greater than 500 μm increases the kerf loss and thus reduces the number of semiconductor wafers produced from slicing one monocrystalline ingot. A preferred wire diameter is 70 to 400 μm. Within this range, semiconductor wafers are efficiently produced without wire breakage.

Examples of the abrasive grain material to be fixed to the wire may include diamond, silica, SiC, alumina, and zirconia. Diamond is particularly preferred.

The grain size (average grain size) of the abrasive grains to be fixed to the wire is 1 to 100 μm. At less than 1 μm, performance of the fixed abrasive grain wire declines in slicing the monocrystalline ingot. At greater than 100 μm, the abrasive grains are likely to separate from the wire and the kerf loss also increases. A preferred average grain size is 5 to 40 μm. Within this range, high-quality semiconductor wafers are produced that have reduced warpage and process damage on a sliced surface.

To fix the abrasive grains to the external peripheral surface of the wire, for instance, the abrasive grains may be deposited on the external peripheral surface of the wire using a thermoset resin binder or a photo-curable resin binder, which is then thermally cured or photo-cured. Alternatively, the abrasive grains may be electrodeposited on the external peripheral surface of the wire or an electrolytic plating layer may be formed on the external peripheral surface of the wire to implant the abrasive grains. The wire to be used is not limited to an electrodeposited abrasive grain wire, but may be a resin bond wire.

The processing liquid to be supplied to the row of wires during the slicing is pure water free from free abrasive grains, such as silica particles.

An example of pure water (ultrapure water) may be water having a purity level at which an amount of dissolved matter, such as sodium, iron, copper, and zinc, per one liter of water is one billionth of a gram (μg/l) to one trillionth of a gram (ng/l). To inhibit the wires from being clogged with cut scraps, a small amount of a thickener may be added to the pure water to be supplied. Examples of the additive may include alcohols and glycols, such as ethylene glycol, diethylene glycol, and propylene glycol. This increases viscosity of the pure water and discharges the cut scraps in a highly effective manner.

The feeding speed of the fixed abrasive grain wire is 0.05 to 2.00 m/min. At less than 0.05 m/min, performance of the fixed abrasive grain wire declines in slicing the monocrystalline ingot. At greater than 2.00 m/min, a wire may break. A preferred feeding speed of the fixed abrasive grain wire is 0.2 to 1.0 m/min. Within this range, high-quality semiconductor wafers are produced that have reduced warpage and process damage on the sliced surface.

To grind the front and rear surfaces of the semiconductor wafer with fixed abrasive grains, a sun gear (planetary gear) system or a non-sun gear system may be employed. In the non-sun gear system, a carrier plate performs a circular motion without rotation to simultaneously grind the front and rear surfaces of the semiconductor wafer. During the double-side grinding with fixed abrasive grains, rough grinding and precision grinding are performed in series, the rough grinding increasing the parallelism of the front and rear surfaces of the semiconductor wafer, the precision grinding increasing the flatness of the front and rear surfaces of the roughly ground semiconductor wafer. The grinding may be performed in a single wafer manner that treats each semiconductor wafer individually, or in a batch manner that treats a plurality of semiconductor wafers simultaneously. In the grinding process, the front and rear surfaces of the semiconductor wafer may be treated simultaneously or each surface may be treated individually.

In the non-sun gear double-side grinding, a fixed abrasive grain processor is used. Examples of the fixed abrasive grain processor may include a double-side grinder and a double-side polisher.

Such a non-sun gear fixed abrasive grain processor is specifically configured to include, for example, a grinding lower platen, a grinding upper platen, a carrier plate, and a carrier circular motion mechanism, the grinding lower platen having an upper surface (platen surface) on which a fixed abrasive grain layer is provided to grind one surface of a semiconductor wafer, the grinding upper platen being disposed directly above the grinding lower platen and having a lower surface (platen surface) on which another fixed abrasive grain layer is provided to grind the other surface of the semiconductor wafer, the carrier plate being provided between the grinding lower platen and the grinding upper platen and having a plurality of wafer holding holes for the semiconductor wafer, and the carrier circular motion mechanism causing the carrier plate to perform a circular motion without rotation between the grinding lower platen and the grinding upper platen so as to simultaneously grind, with the fixed abrasive grain layers, front and rear surfaces of each of a plurality of semiconductor wafers held by the wafer holding holes.

A rotation speed of the grinding upper platen and the grinding lower platen is 5 to 30 rpm. At less than 5 rpm, a processing rate of semiconductor wafers declines. At greater than 30 rpm, a semiconductor wafer may fall out of the wafer holding holes during processing. A preferred rotation speed of the two platens is 10 to 25 rpm. Within this range, the double-side grinding of the semiconductor wafers is achieved at a stable processing rate, and the flatness can be maintained.

The two platens may be rotated at the same speed or at different speeds. The grinding upper platen and the grinding lower platen may be rotated in the same direction or in different directions. Since the carrier plate performs a circular motion without rotation during wafer processing, the two platens do not necessarily need to be rotated.

The circular motion without rotation herein means a circular motion in which the carrier plate revolves (swings and spins) while constantly maintaining eccentricity at a predetermined distance from the axes of the grinding upper platen and the grinding lower platen. With the circular motion without rotation, all points on the carrier plate follow trajectories of small circles each having the same size (radius r).

Such a non-sun gear fixed abrasive grain processor, which does not have a sun gear such as in a planetary gear type, is suitable for a large-diameter wafer having a diameter of 300 mm or greater, for example.

Any number of wafer holding holes may be formed in the carrier plate. For example, one hole may be provided. Alternatively, two to five holes or more than five holes may be provided.

The speed of the circular motion without rotation of the carrier plate is 1 to 15 rpm. At less than 1 rpm, a wafer surface is not ground evenly. At greater than 15 rpm, an edge surface of a semiconductor wafer held by the wafer holding holes is damaged.

An example of each of the fixed abrasive grain layers may include an elastic base material to which the fixed abrasive grains having a grain size (average grain size) of less than 4 μm are fixed in a dispersed state. Within this range, scratches do not occur in the processed surface of the semiconductor wafer and a high processing rate can be maintained. At 4 μm or greater, scratches are likely to occur in a processed surface of a semiconductor wafer. A preferred grain size of the fixed abrasive grains is 0.5 μm or greater and less than 4 μm. Within this range, stable processing can be achieved with hardly any clogging.

The thickness of the fixed abrasive grain layer is 0.1 to 15 mm. At less than 0.1 mm, the base material that holds the fixed abrasive grain layer comes into contact with a wafer. At greater than 15 mm, the fixed abrasive grain layer declines in strength and is damaged. A preferred thickness of the fixed abrasive grain layer is 0.5 to 10 mm. Within this range, stable grinding of the semiconductor wafers can be achieved and the life of the fixed abrasive grain layer is prolonged.

Examples of the fixed abrasive grain material may include diamond, silica, SiC, alumina, and zirconia.

The degree of concentration of the fixed abrasive grains is 50 to 200, for example. At less than 50 (12.5 volume %), performance in processing semiconductor wafers declines, while at greater than 200 (50 volume %), self-shaping of the (fixed) abrasive grains declines. The degree of concentration represents the number of abrasive grains in a grinding stone. A content rate of the abrasive grains in a bond (elastic base material) of 25 volume % is defined as 100. A preferred degree of concentration of the fixed abrasive grains is 100 (25 volume %) to 150 (37.5 volume %). Within this range, stable grinding of the semiconductor wafers is achieved and the life of the fixed abrasive grain layer is prolonged.

Examples of the elastic base material may include curable polymers (epoxy resin, phenol resin, acrylic urethane resin, polyurethane resin, vinyl chloride resin, and fluorine resin).

The surface pressure to the semiconductor wafer during the double-side grinding is 250 to 400 g/cm², for example. Within this range, stable grinding of the semiconductor wafers can be achieved with no reduction in the processing rate. At less than 250 g/cm², the processing rate of the semiconductor wafers declines, while at greater than 400 g/cm², the semiconductor wafer cracks due to a high weight load.

As the processing liquid to be supplied to the semiconductor wafer during the simultaneous grinding of the front and rear surfaces thereof, pure water free from free abrasive grains may be used in a similar way as during slicing. A small amount of the thickener described above may be added to the pure water to inhibit the fixed abrasive grain layer from being clogged with the cut scraps.

Examples of a chamfering grindstone used to chamfer the external peripheral portion of the semiconductor wafer may include #800 to #1500 metal bonded grinding stones for chamfering. A chamfering amount herein is 100 to 1,000 To smoothen the processing, pure water free from free abrasive grains is supplied to the external peripheral surface of the wafer during the chamfering.

The front and rear surfaces of the semiconductor wafer are polished such that the roughness of the front and rear surfaces of the polished semiconductor wafer is 100 nm or less in RMS. The polishing may be performed simultaneously on the front and rear surfaces of the semiconductor wafer or on one surface at a time.

A polishing cloth used for polishing the front and rear surfaces may be a urethane type having an Asker hardness of 75 to 85 and a compression rate of 2 to 3%. Polyurethane is preferred as a material of the polishing cloth. In particular, polyurethane foam is preferred due to its excellent degree of precision in mirror-polishing a wafer surface. Alternatively, a suede polyurethane or polyester unwoven fabric may be employed.

Conditions for mirror-polishing the front and rear surfaces include, for example, a polishing rate of 0.2 to 0.6 μm/min, a polishing amount of 5 to 20 μm, a polishing load of 200 to 300 g/cm², a polishing time of 10 to 90 minutes, and a temperature of a polishing liquid during polishing of 20 to 30° C. The polishing liquid may or may not include the free abrasive grains. Examples of the polishing liquid including the free abrasive grains may include a variety of alkaline aqueous solutions (such as KOH aqueous solution and NaOH aqueous solution) as a primary liquid dispersed with silica having an average grain size of 20 to 40 μm. Examples of the polishing liquid free from free abrasive grains may include a variety of alkaline aqueous solutions described above as the primary liquid.

Examples of the polisher of the front and rear surfaces of the semiconductor wafer may include a sun gear (planetary gear) type or a non-sun gear type in which a carrier plate performs a circular motion without rotation to simultaneously polish the front and rear surfaces of the semiconductor wafer.

A single wafer type double-side polisher or a batch type double-side polisher which simultaneously polishes a plurality of semiconductor wafers may be used.

A second aspect of the present invention provides the method of manufacturing a semiconductor wafer according to the first aspect, in which waste water including semiconductor scraps generated in each process that uses the pure water is collected in one water tank, and then the semiconductor scraps are collected from the waste water.

According to the second aspect of the present invention, the waste water including semiconductor scraps generated in the slicing process, the grinding process, and the chamfering process, in each of which predetermined processing is performed while the pure water is supplied, is collected in one water tank, and then the semiconductor scraps separated and collected from the waste water undergo a predetermined recycling process such that the semiconductor scraps are recycled.

Thus, the pure water free from free abrasive grains is used as a processing liquid (lubricating liquid) to be supplied to the monocrystalline ingot during the slicing and to the semiconductor wafer during the grinding of the front and rear surfaces and the chamfering, and then the waste water from each process is collected in one water tank for the recycling process. Accordingly, the recycling process is easy and the processing cost is reduced, compared to a conventional case in which semiconductor scraps are individually collected from a used slurry including a large amount of free abrasive grains and the collected semiconductor scraps are individually recycled as raw material for monocrystalline silicon.

The semiconductor scraps include ground scraps of the monocrystalline ingot generated during the slicing, ground scraps of the semiconductor wafer generated during the grinding, and ground (chamfered) scraps of the wafer external peripheral portion generated during the chamfering.

Examples of a method of collecting the semiconductor scraps from the waste water may include a natural sedimentation method and a centrifugal separation method. The collected semiconductor scraps are heat-dried and then formed into a mass of an easily-handled size.

To recycle the collected semiconductor scraps, collected supernatant water may be heated and evaporated.

A third aspect of the present invention provides the method of manufacturing a semiconductor wafer according to the first or second aspect, in which the grinding simultaneously grinds the front and rear surfaces of the semiconductor wafer by placing the semiconductor wafer between the fixed abrasive grain layer formed on a lower surface of the grinding upper platen and the other fixed abrasive grain layer formed on an upper surface of the grinding lower platen and by rotating the grinding upper platen and the grinding lower platen relative to the semiconductor wafer, and the polishing simultaneously polishes the front and rear surfaces of the semiconductor wafer to finish polish one of the front surface and the front and rear surfaces of the polished semiconductor wafer.

The grinding process is simultaneous double-side grinding in which the front and rear surfaces of the semiconductor wafer are simultaneously ground. The polishing process is simultaneous double-side polishing in which the front and rear surfaces of the semiconductor wafer are simultaneously polished.

The finish polishing is high-precision polishing performed on the front surface (polished surface) or the front and rear surfaces of the semiconductor wafer. For the finish polishing, a suede type polishing cloth for finish polishing is used that has a hardness (Shore hardness) of 60 to 70, a compression rate of 3 to 7%, and a compressive elastic modulus of 50 to 70%. A polishing agent includes free abrasive grains (silica) having an average grain size of 20 to 40 nm.

Conditions for finish polishing include, for example, a polishing pressure of approximately 100 g/cm², a polishing amount of approximately 0.1 μm, and a surface roughness of 0.1 nm or less in RMS. The finish polishing is mirror-polishing performed at least on the wafer front surface (device forming surface).

For finish polishing only the front surface of the semiconductor wafer (also applicable to finish polishing of the front and rear surfaces), a single-side mirror-polisher may be used in which, for example, a polishing head to which a semiconductor wafer is fixed with the front surface thereof downward is rotated and gradually lowered to be above a polishing platen in which a polishing cloth is bonded to the upper surface thereof and is pressed at a predetermined pressure against the polishing cloth bonded to the upper surface of the polishing platen.

### Advantageous Effects of Invention

According to the first aspect of the present invention, semiconductor wafers are processed in double-side grinding of a fixed abrasive grain type that allows processes from rough grinding to finish grinding to be completed in one process, thus achieving a reduction in the number of processes to manufacture the semiconductor wafers. In addition to the double-side grinding of the fixed abrasive grain type, a monocrystalline ingot is sliced by a fixed abrasive grain wire during slicing, thus reducing the kerf loss during wafer production.

Furthermore, the slicing with the fixed abrasive grain wire and the double-side grinding of the fixed abrasive grain type by the upper and lower platens reduce an amount of the abrasive grains included in a used processing liquid discharged in the slicing process, the double-side grinding process, and the chamfering process, including the chamfering process that uses the chamfering grindstone, compared to a conventional case with a slurry including free abrasive grains. In addition, employing the fixed abrasive grain type allows use of the pure water as the processing liquid used in the three processes and thus facilitates a recycling process and reduces processing cost, compared to a conventional case where semiconductor scraps are collected for recycling from a used slurry that includes an oil dispersant and the free abrasive grains.

According to the second aspect of the invention, the pure water free from free abrasive grains is used as the processing liquid to be supplied to the monocrystalline ingot during the slicing and to the semiconductor wafer during the grinding of the front and rear surfaces and the chamfering, and then the waste water from each process is collected in one water tank for the recycling process. Thus, the recycling process is easy and the processing cost is reduced, compared to a conventional case in which semiconductor scraps are individually collected from a used slurry including a large amount of free abrasive grains and the collected semiconductor scraps are individually recycled as raw material for monocrystalline silicon.

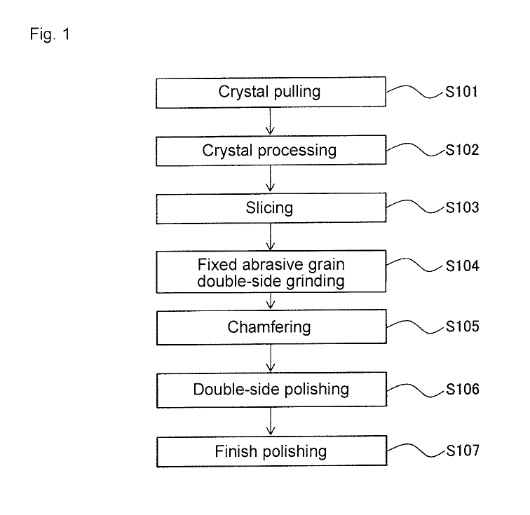

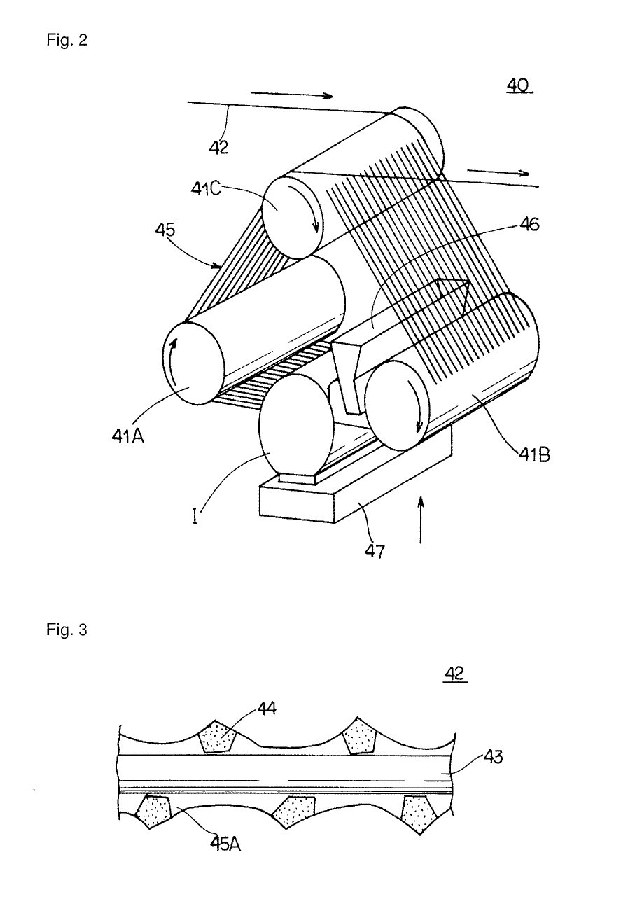

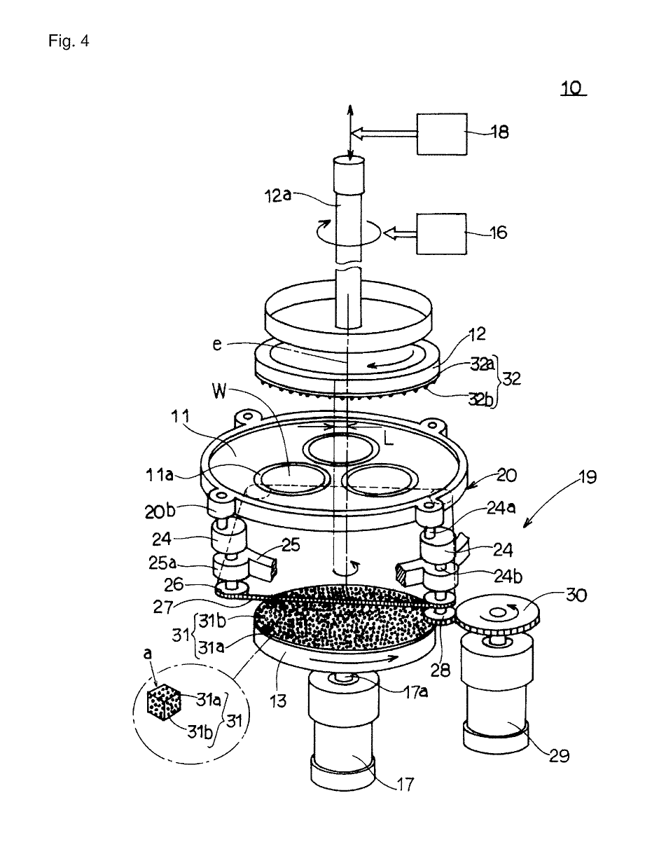

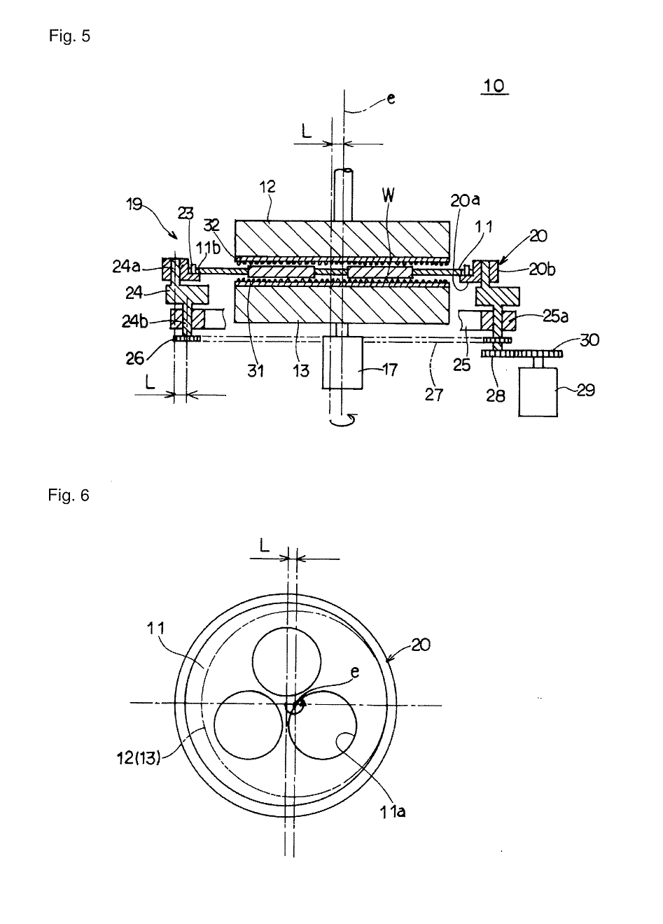

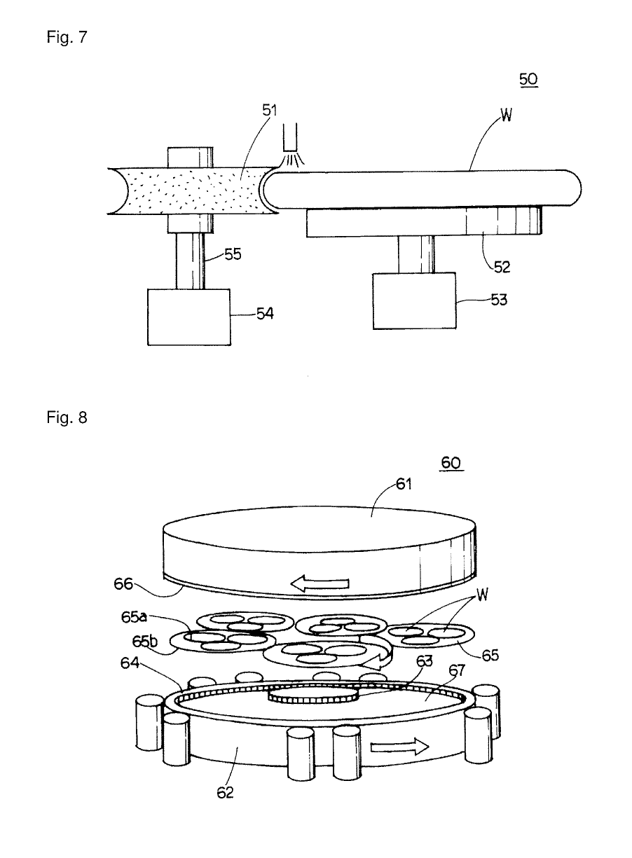

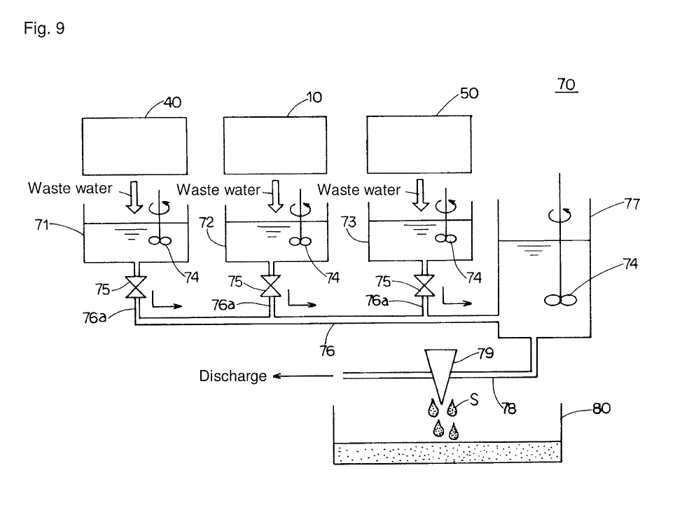

### BRIEF DESCRIPTION OF DRAWINGS

[FIG. 1] A flow sheet illustrating a method of manufacturing a semiconductor wafer according to a first embodiment of the present invention.

[FIG. 2] A perspective view illustrating a slicing process in the method of manufacturing the semiconductor wafer according to the first embodiment of the present invention.

[FIG. 3] A partially enlarged cross-sectional view of a fixed abrasive grain wire used in the slicing process in the method of manufacturing the semiconductor wafer according to the first embodiment of the present invention.

[FIG. 4] A perspective view of a fixed abrasive grain processor used in a process of simultaneously grinding front and rear surfaces of the wafer in the method of manufacturing the semiconductor wafer according to the first embodiment of the present invention.

[FIG. 5] A vertical cross-sectional view illustrating a state of use of the fixed abrasive grain processor used in the simultaneous grinding process in the method of manufacturing the semiconductor wafer according to the first embodiment of the present invention.

[FIG. 6] A plan view illustrating a circular motion without rotation of a carrier plate of the fixed abrasive grain processor used in the process of simultaneously grinding the front and rear surfaces in the method of manufacturing the semiconductor wafer according to the first embodiment of the present invention.

[FIG. 7] A front view illustrating a state of use of a chamfering device used in a process of chamfering the semiconductor wafer in the method of manufacturing the semiconductor wafer according to the first embodiment of the present invention.

[FIG. 8] A perspective view of a planetary gear type double-side polisher used in a process of polishing two surfaces of the semiconductor wafer in the method of manufacturing the semiconductor wafer according to the first embodiment of the present invention.

[FIG. 9] A front view illustrating a system for recycling semiconductor scraps from waste water of the slicing process, the process of simultaneously grinding the front and rear surfaces, and the chamfering process in the method of manufacturing the semiconductor wafer according to the first embodiment of the present invention.

### REFERENCE SIGNS LIST

12: Upper platen (grinding upper platen)

13: Lower platen (grinding lower platen)

31: Lower processing layer (fixed abrasive grain layer)

31b: Diamond abrasive grain

32: Upper processing layer (another fixed abrasive grain layer)

32b: Diamond abrasive grain

40: Wire saw

42: Fixed abrasive grain wire

44: Diamond abrasive grain

51: Chamfering grinding stone

77: Collection tank (water tank)

I: Crystal block (monocrystalline ingot)

S: Silicon scrap (semiconductor scrap)

W: Silicon wafer (semiconductor wafer)

### DESCRIPTION OF EMBODIMENTS

Embodiments of the present invention are described below in detail.

### First Embodiment

A method of manufacturing a semiconductor wafer according to a first embodiment of the present invention is explained with reference to a flow sheet in FIG. 1.

Specifically, the method of manufacturing the semiconductor wafer according to the first embodiment includes in sequence a crystal pulling process S101, a crystal processing process S102, a slicing process S103, a fixed abrasive grain double-side grinding process S104, a chamfering process S105, a double-side polishing process S106, and a finish polishing process S107.

Each process is described specifically below.

In the crystal pulling process S101, a monocrystalline silicon ingot is pulled in the Czochralski process from molten silicon liquid doped with a predetermined amount of boron in a crucible, the monocrystalline silicon ingot having a diameter of 306 mm, a length of a straight body portion of 2,500 mm, a resistivity of 0.01 Ω·m, and an initial oxygen concentration of 1.0 ×10¹⁸ atoms/cm³.

In the subsequent crystal processing process S102, one monocrystalline silicon ingot is cut into a plurality of crystal blocks I, each of whose external peripheries is then ground. Specifically, the external peripheral portion of each of the crystal blocks I is ground only for 6 mm by an external periphery grinder having a resinoid grinding stone that includes #200 abrasive grains (SiC). Each of the crystal blocks I is thus formed into a cylindrical shape.

In the slicing process S103, a wire saw 40 is used to slice each of the crystal blocks I into numerous silicon wafers each having a diameter of 300 mm.

With reference to FIG. 2, the wire saw 40 has three wire saw groove rollers (hereinafter referred to as groove rollers) 41A to 41C positioned in a triangle shape from a front view. One fixed abrasive grain wire 42 is wound around the groove rollers 41A to 41C so as to be parallel with itself at a constant pitch. Thus, a row of wires 45 appears around the groove rollers 41A to 41C.

The fixed abrasive grain wire 42 is a steel wire 43 having a diameter of 160 μm and a surface on which diamond abrasive grains 44 each having a grain size of 15 to 25 μm are fixed with a nickel plating 45A having a thickness of 7 μm) (FIG. 3).

The fixed abrasive grain wire 42 is fed from a bobbin of a feeder, is passed around the respective groove rollers 41A to 41C via a supply guide roller, and then is rolled up around a bobbin of a winder via a feeding guide roller. The fixed abrasive grain wire 42 is reciprocated, and thus the functions of the feeder and the winder are alternated. The row of wires 45 is reciprocated among the three groove rollers 41A to 41C by a main motor. A middle portion between the two groove rollers 41A and 41B disposed on the lower side is a cutting position of the crystal block I. A pure water supply nozzle 46 is provided in one upper side portion of the cutting position to continuously supply pure water on the row of wires 45. While the pure water is supplied from the pure water supply nozzle 46 at a rate of 10 l/min to the row of wires 45, the crystal block I is pressed from below at a rate of 1.0 mm/min against the row of wires 45 reciprocating at a rate of 1 m/min.

In FIG. 2, an elevation stage 47 is provided for the crystal block I.

In the fixed abrasive grain double-side grinding process S104, a non-sun gear fixed abrasive grain processor is used to simultaneously grind the front and rear surfaces of the silicon wafer while pure water is supplied.

With reference to FIGS. 4 to 6, a fixed abrasive grain processor 10 is described in detail.

The fixed abrasive grain processor 10 has a carrier plate 11, an upper platen (grinding upper platen) 12, and a lower platen (grinding lower platen) 13. The carrier plate 11, which is formed of glass epoxy, has a circular plate shape from a plan view in which three wafer holding holes 11 a are provided every 120° around a plate axis (in a circumferential direction). The upper platen 12 and the lower platen 13 sandwich a silicon wafer W which is rotatably inserted and held in each of the wafer holding holes 11a and grind the front and rear surfaces of the wafer by moving relative to the silicon wafer W. The thickness of the carrier plate 11 (700 μm) is slightly less than the thickness of the silicon wafer W (780 μm).

A lower processing layer (fixed abrasive grain layer) 31 is provided on an upper surface (platen surface) of the lower platen 13. An upper processing layer (another fixed abrasive grain layer) 32 is provided on a lower surface (platen surface) of the upper platen 12. The lower processing layer 31 and the upper processing layer 32 have elastic base materials 31a and 32a, respectively. On an entire surface of each of the elastic base materials 31a and 32a, diamond abrasive grains (fixed abrasive grains) 31b and 32b, respectively, each having a grain size (average grain size) of less than 4 μm (e.g., 0.5 μm or greater and less than 4 μm), are provided by bonding grindstone pieces a of several mm cubes (0.1 mm cubes to 10 mm cubes) at a concentration ratio of 100 with an adhesive. As a material for the elastic base materials 31a and 32a, curable polymers (e.g., epoxy resin, phenol resin, acrylic urethane resin, polyurethane resin, vinyl chloride resin, and fluorine resin) are employed. The thickness is 800 μm. In this embodiment, the grindstone pieces a that include the diamond abrasive grains 31b and 32b are bonded on the surfaces of the elastic base materials 31a and 32a to form the two processing layers 31 and 32, respectively. Alternatively, the diamond abrasive grains 31b and 32b may be directly bonded to the surfaces of the elastic base materials 31a and 32a to form the two processing layers 31 and 32, respectively.

The upper platen 12 is rotated and driven within a horizontal plane by an upper rotating motor 16 through a rotating axis 12a extending upward. The upper platen 12 is vertically moved up and down by a lift 18 that moves the upper platen 12 in an axial direction. The lift 18 is used to supply and eject the silicon wafer W to and from the carrier plate 11, for example. A surface pressure of 250 g/cm² on the front and rear surfaces of the silicon wafer W from the upper platen 12 and the lower platen 13 is exerted by a pressing unit, such as an air bag (not shown in the drawings), installed in each of the upper platen 12 and the lower platen 13.

The lower platen 13 is rotated within the horizontal plane by a lower rotating motor 17 through an output axis 17a. A carrier circular motion mechanism 19 allows the carrier plate 11 to perform a circular motion within a plane parallel to a surface of the plate 11 (horizontal plane) such that the plate 11 itself does not rotate.

The carrier circular motion mechanism 19 is described in detail below with reference to FIGS. 4 to 6.

The carrier circular motion mechanism 19 has an annular carrier holder 20 that externally holds the carrier plate 11. The carrier circular motion mechanism 19 and the carrier holder 20 are connected through an interlock structure. The interlock structure interlocks the carrier plate 11 to the carrier holder 20 such that the carrier plate 11 does not rotate while absorbing growth of the carrier plate 11 during thermal expansion.

Specifically, with reference to FIGS. 4 and 5, the interlock structure includes a plurality of pins 23 and elongated pin holes 11b. The pins 23 are provided in an internal peripheral flange 20a of the carrier holder 20 and project every predetermined angle in the holder circumferential direction. The pin holes 11b are provided in an external peripheral portion of the carrier plate 11 at positions corresponding to the pins 23 in a number corresponding thereto.

A length direction of each of the pin holes 11b is aligned with a radius direction of the plate such that the carrier plate 11 interlocked to the carrier holder 20 through the pins 23 can move slightly in the radius direction. Mounting the carrier plate 11 to the carrier holder 20 by inserting the pins 23 through the pin holes 11b absorbs expansion due to thermal expansion of the carrier plate 11 during double-side grinding. The flange 20a on which the carrier plate 11 is mounted is provided in the periphery immediately above an external thread at a base portion of each of the pins 23.

Four axis receivers 20b projecting externally at 90° intervals are provided to an external peripheral portion of the carrier holder 20. Each of the axis receivers 20b is mounted with an eccentric axis 24a, which projects at an eccentric position on an upper surface of an eccentric arm 24 having a small-diameter circular plate shape. A rotation axis 24b is provided perpendicularly at a central portion of a lower surface of each of the four eccentric arms 24. Each of the rotation axes 24b is mounted to each of axis receivers 25a provided at 90° intervals to an annular apparatus main body 25 in a state in which an end portion of the rotation axis 24b projects downward. A sprocket 26 is fixed to the downward projecting end portion of each of the rotation axes 24b. A timing chain 27 is continuously provided to the sprockets 26 in a horizontal state. The sprockets 26 and the timing chain 27 form a synchronization unit that rotates the four rotation axes 24b simultaneously such that the four eccentric arms 24 perform a circular motion synchronously.

One of the four rotation axes 24b is longer such that the end portion projects downward further than the sprocket 26. A gear 28 for power transmission is fixed to this portion. The gear 28 is engaged with a large-diameter drive gear 30, which is fixed to the output axis extending upward of a circular motion motor 29, such as, for example, a geared motor. Instead of using the timing chain 27 for synchronization, the circular motion motor 29 may be provided to each of the eccentric arms 24 to individually rotate the eccentric arms 24.

With rotation of the output axis of the circular motion motor 29, the rotation force thereof is transmitted to the timing chain 27 through the gears 30 and 28 and the sprocket 26 fixed to the long rotation axis 24b. Through the remaining three sprockets 26, circumferential rotation of the timing chain 27 synchronously rotates the four eccentric arms 24 centered on the rotation axes 24b and within the horizontal plane. Thereby, the carrier holder 20 collectively connected to the eccentric axes 24a, and hence the carrier plate 11 held by the holder 20, performs a circular motion without rotation, within the horizontal plane parallel to the plate 11.

Specifically, the center line of the carrier plate 11 revolves in an eccentric state with a distance L from an axial line e of the two platens 12 and 13. The distance L is identical to a distance between the eccentric axis 24a and the rotation axis 24b. The circular motion without rotation allows all points on the carrier plate 11 to follow trajectories of small circles each having the same size (FIG. 6).

A method of processing the silicon wafer W using the fixed abrasive grain processor 10 is described below with reference to FIGS. 4 to 6.

First, one silicon wafer W is rotatably inserted to each of the wafer holding holes 11 a of the carrier plate 11. In this state, the upper processing layer 32 rotating at a rate of 15 rpm together with the upper platen 12 is then pressed against each wafer W at a rate of 250 g/cm², while the lower processing layer 31 rotating at a rate of 15 rpm together with the lower platen 13 is pressed against each wafer front surface at a rate of 250 g/cm².

Thereafter, in the state where the two processing layers 31 and 32 are pressed against the front and rear surfaces of the wafer, the timing chain 27 is circumferentially rotated by the circular motion motor 29 while pure water is supplied at a rate of 2 l/min from the upper platen 12. Thus, the respective eccentric arms 24 are rotated synchronously within the horizontal plane, and the carrier holder 20 and the carrier plate 11 collectively interlocked to the eccentric axes 24a perform a circular motion without rotation at a rate of 7.5 rpm within the horizontal plane parallel to the front surface of the plate 11. Accordingly, each silicon wafer W circulates within the horizontal plane in the corresponding wafer holding hole 11a, and the front and rear surfaces of three silicon wafers W are simultaneously ground. The grinding amount is 30 μm for one surface of the wafer and 60 μm for the front and rear surfaces of the wafer (processing strain is 15 μm for one surface and 30 μm for two surfaces).

As described above, the silicon wafers W are processed three at a time using the fixed abrasive grain processor 10 of the fixed abrasive grain type that performs processes from rough grinding to finish grinding in one process, thus reducing the number of manufacturing processes of the silicon wafers W. In addition to the simultaneous double-side grinding of the fixed abrasive grain type, the crystal block I is sliced by the fixed abrasive grain wire 42 during the slicing, thus reducing a kerf loss in wafer production.

With the use of the non-sun gear type fixed abrasive grain processor 10, the surface pressure is 250 g/cm², which is higher than that of a sun gear type (100 to 150 g/cm²), to simultaneously grind the front and rear surfaces of each of the silicon wafers W during the circular motion without rotation. This achieves highly precise processing that hardly causes scratches in the ground surface (processed surface) even at a high processing rate of 15 μm/min.

Furthermore, the fixed abrasive grain processor 10 is used to process the silicon wafer W with the diamond abrasive grains 31b and 32b each less than 4 μm and bonded to the surfaces of the elastic base materials 31a and 32a, and thus surfaces having good flatness can be produced on the sliced silicon wafer W. The silicon wafer W is placed in a free state in the wafer holding hole 11a of the carrier plate 11. In addition to good flatness, good nanotopography (waviness that appears in the surface of the silicon wafer W in a non-adsorbed state) can thus be achieved.

In addition, the elastic base materials 31a and 32a having elasticity reduces the force received on the silicon wafer W from the diamond abrasive grains 31b and 32b when the diamond abrasive grains 31b and 32b are pressed against the silicon wafer W, thus preventing scratches on the silicon wafer W caused by an external force locally and excessively exerted on the silicon wafer W.

Furthermore, employing a method of wafer processing in which the diamond abrasive grains 31b and 32b are fixed to the upper platen 12 and the lower platen 13 of the fixed abrasive grain processor 10 allows the use of the fine diamond abrasive grains 31b and 32b which are less than 4 μm. Specifically, a conventional lapping device, for example, uses free abrasive grains as the abrasive grains, and thus has difficulty when grain size is made finer.

In the subsequent chamfering process S105, a rotating chamfering grindstone 51 of a chamfering device 50 is pressed against an external peripheral portion of the silicon wafer W for chamfering (FIG. 7).

The chamfering device 50 used in this process chamfers the external peripheral portion of the silicon wafer W by pressing the external peripheral portion of the wafer against a grinding surface (external peripheral surface) of the rotating #800 chamfering grindstone 51.

The silicon wafer W is vacuum-suctioned to an upper surface of a rotation table 52, which is rotatable by a table motor 53. The chamfering grindstone 51 is disposed proximate to the rotation table 52. The chamfering grindstone 51 is fixed to a front end of a rotation axis 55 of a rotation motor 54 and is supported so as to be rotatable around the rotation axis 55. Pure water is supplied at a rate of 5 l/min to a chamfered surface of the silicon wafers during the chamfering.

After the chamfering process S105, the chamfered surface of the silicon wafer W may be mirror-chamfered. Specifically, the chamfered portion of the silicon wafer W (chamfered surface) is pressed against a cloth or buff rotating around a vertical rotation axis, and thus the chamfered surface of the chamfered portion is mirror-finished.

In the subsequent double-side polishing process S106, front and rear surfaces (two sides) of a plurality of silicon wafers W are simultaneously polished with a planetary gear type double-side polisher and a polishing liquid including free abrasive grains.

A planetary gear type double-side polisher 60 is specifically described below with reference to FIG. 8.

The double-side polisher 60 has an upper platen 61 and a lower platen 62 which are disposed in parallel, a small-diameter sun gear 63 provided between the platens 61 and 62 and rotatable around an axis line, a large-diameter internal gear 64 rotatably provided around the same axis line, and four carrier plates 65 each having a small-diameter circular plate shape. An upper polishing cloth 66 is stretched over a lower surface of the upper platen 61 and a lower polishing cloth 67 is stretched over an upper surface of the lower platen 62. Each of the carrier plates 65 has four wafer holding holes 65a. An external gear 65b to be engaged with the sun gear 63 and the internal gear 64 is provided in an external edge portion of each of the carrier plates 65.

A method of simultaneously polishing the front and rear surfaces of the silicon wafer W with the double-side polisher 60 is described.

Each of the carrier plates 65 is rotated and revolved between the upper platen 61 and the lower platen 62 while the polishing liquid is supplied. The front and rear surfaces of silicon wafers W supported by the wafer holding holes 65a of the respective carrier plates 65 are pressed against the corresponding upper polishing cloth 66 and lower polishing cloth 67 and are thus mechanically and chemically polished in a batch. The polishing liquid is colloidal silica, which is an aqueous solution containing dispersed pyrogenic silica. At this time, the sun gear 63 and the internal gear 64 are rotated in opposite directions to each other. Thus, the front and rear surfaces of each of the silicon wafers W are polished simultaneously only for 20 μm.

In the subsequent finish polishing process S107, the front surfaces of the plurality of silicon wafers W are mirror finish polished with a single-side polisher (not shown in the drawing).

The single-side polisher has a polishing platen and a polishing head provided thereabove, the polishing platen having an upper surface over which a polishing cloth formed of a hard urethane pad is stretched. Three silicon wafers W having the front surfaces facing downward are bonded with wax to a lower surface of the polishing head through a carrier plate.

During single-side polishing, while the polishing platen and the polishing head are rotated in a predetermined direction at a predetermined rate, the polishing head is gradually lowered and then is pressed against the polishing cloth to which the polishing liquid is supplied at a rate of 5 l/min. Thus, the front surface of each of the silicon wafers W is mirror-polished only for 0.5 μm.

As described above, the slicing with the wire saw 40 using the fixed abrasive grain wire 42 and the simultaneous double-side grinding with the grinding upper and lower platens 12 and 13 of the fixed abrasive grain processor 10 reduce an amount of abrasive grains included in the used processing liquid (waste water) discharged in the slicing, simultaneous double-side grinding, and chamfering processes, including the chamfering process that uses the chamfering device 50, compared to a conventional polishing liquid including free abrasive grains (slurry).

In addition, using the fixed abrasive grain type allows use of pure water as the processing liquid used in the three processes. Accordingly, employing a recycle system 70 for silicon scraps, as shown in FIG. 9, facilitates a recycling process and reduces processing cost, compared to a conventional case where the silicon scraps (semiconductor scraps) are collected for recycling from a used slurry that includes an oil dispersant and free abrasive grains.

The recycle system 70 is described that collects silicon scraps from the waste water from the wire saw 40, the fixed abrasive grain processor 10, and the chamfering device 50.

The recycle system 70 has a first sub tank 71 storing the waste water from the wire saw 40, a second sub tank 72 storing the waste water from the fixed abrasive grain processor 10, and a third sub tank 73 storing the waste water from the chamfering device 50. Each of the sub tanks 71 to 73 is provided with a stirrer 74 stirring the stored waste water. An upstream end portion of a branch pipe 76a, in the middle of which an open/close valve 75 is provided, is connected to a bottom plate of each of the sub tanks 71 to 73. A downstream end portion of each branch pipe 76a is connected to an upstream end portion, a middle portion in a length direction, or a downstream portion of an inlet pipe 76 connected to an interior of a bottom portion of a collection tank (water tank) 77.

The waste water in the sub tanks 71 to 73 is introduced to a collection tank 77 through the respective branch pipes 76a and the inlet pipe 76. The three kinds of waste water are dispersed and mixed therein by the stirrer 74, and then the waste water is discharged to an exterior through an outlet pipe 78. During the discharge, silicon scraps S are centrifuged from the mixed waste water by a cyclone separator 79 provided in a middle portion of the outlet pipe 78. The separated silicon scraps S are dropped directly below and collected in a scrap receiving tank 80. Thereafter, the collected silicon scraps S undergo a post-process of metal removal cleaning. The post-processed silicon scraps S are placed into a crucible of a Czochralski process monocrystalline silicon pulling device to be recycled as raw material for a monocrystalline silicon ingot.

### INDUSTRIAL APPLICABILITY

The present invention is effective in reducing industrial waste (semiconductor scrap) discharged from a semiconductor manufacturing plant and in recycling the industrial waste.

1. A method of manufacturing a semiconductor wafer, comprising:
slicing a semiconductor monocrystalline ingot into a plurality of semiconductor wafers by using a fixed abrasive grain wire having an external peripheral surface to which abrasive grains are fixed;
grinding front and rear surfaces of each of the semiconductor wafers by using fixed abrasive grain layers formed on platen surfaces;
chamfering an external peripheral portion of each of the ground semiconductor wafers by using a chamfering grindstone; and
polishing the front and rear surfaces of each of the ground semiconductor wafers, wherein
the slicing, the grinding, and the chamfering are performed while pure water free from free abrasive grains is supplied to one of the monocrystalline ingot and the semiconductor wafers.

2. The method of manufacturing a semiconductor wafer according to claim 1, wherein waste water including semiconductor scraps generated in each process that uses the pure water is collected in one water tank, and then the semiconductor scraps are collected from the waste water.

3. The method of manufacturing a semiconductor wafer according to claim 1, wherein
the grinding simultaneously grinds the front and rear surfaces of the semiconductor wafer by placing the semiconductor wafer between the fixed abrasive grain layer formed on a lower surface of the grinding upper platen and the other fixed abrasive grain layer formed on an upper surface of the grinding lower platen and by rotating the grinding upper platen and the grinding lower platen relative to the semiconductor wafer, and
the polishing simultaneously polishes the front and rear surfaces of the semiconductor wafer to finish polish one of the front surface and the front and rear surfaces of the polished semiconductor wafer.

4. The method of manufacturing a semiconductor wafer according to claim 2, wherein
the grinding simultaneously grinds the front and rear surfaces of the semiconductor wafer by placing the semiconductor wafer between the fixed abrasive grain layer formed on a lower surface of the grinding upper platen and the other fixed abrasive grain layer formed on an upper surface of the grinding lower platen and by rotating the grinding upper platen and the grinding lower platen relative to the semiconductor wafer, and
the polishing simultaneously polishes the front and rear surfaces of the semiconductor wafer to finish polish one of the front surface and the front and rear surfaces of the polished semiconductor wafer.
